(19) United States
(12) Patent Application Publication
(10) Pub. No.: US 2017/0261820 A1
(43) Pub. Date: Sep. 14, 2017

(54) ARRAY SUBSTRATE AND METHOD FOR MANUFACTURING THE SAME

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Liang LIN, Beijing (CN); Chengshao YANG, Beijing (CN); Tao JIANG, Beijing (CN); Zhixiang ZOU, Beijing (CN); Yinhu HUANG, Beijing (CN)

(21) Appl. No.: 15/528,963

(22) PCT Filed: Sep. 19, 2016
(86) PCT No.: PCT/CN2016/099318

§ 371 Date: May 23, 2017

(30) Foreign Application Priority Data
Oct. 14, 2015 (CN) 201510663063.X

(51) Int. Cl. G02F 1/1343; G02F 1/1362; H01L 27/12; G02F 1/1333

(52) U.S. Cl. CPC G02F 1/134309; G02F 1/13439; G02F 1/133345; G02F 1/136227; G02F 1/1362; H01L 27/1288; H01L 27/1244; G02F 2001/134318; G02F 2201/121; G02F 2202/10; G02F 2201/123; G02F 1/1368

(57) ABSTRACT

The embodiments of the present invention provide an array substrate and a method for manufacturing the same. The method includes: forming an ITO film on a substrate; performing an annealing treatment on the substrate; forming a gate metal film on the ITO film; and processing the ITO film and the gate metal film to obtain a common electrode pattern and a gate pattern. In the embodiments of the present invention, after film formation of ITO, an annealing process is performed. Water vapor residue in the ITO film can thus be released, thereby avoiding bumps on the interface between the ITO and other layers, and improving the yield of ADS products.

### TECHNICAL FIELD

The present invention relates to the field of LCD (liquid crystal display) technology, in particular to an array substrate and a method for manufacturing the same.

### BACKGROUND

TFT (Thin Film Transistor) LCD has become the mainstream of the current display products because of its excellent performance, large-scale production characteristics, and a broad space for development, etc. According to the display mode, TFT LCD can be classified as: TN (Twisted Nematic) type, IPS (In Plane Switching) type and ADS (Advanced Super Dimension Switch) type.

An array substrate of the ADS type LCD includes a substrate, a common electrode, a gate, a semiconductor layer, a source, a drain, a passivation layer and a pixel electrode formed on the substrate in sequence. In order to reduce the fabrication processes of the above mentioned array substrate, there is a 4-mask (4MASK) production process. In particular, the first step is to form a common electrode (1st ITO) and a gate (Gate) on the substrate. The second step is to form a semiconductor layer, a source and a drain (S/D) on the substrate. The third step is to form a passivation layer on the substrate and form a via hole (Via Hole). The fourth step is to form a pixel electrode (2nd ITO) on the substrate. Therefore these 4 masks are: ITO Gate Mask in the first step, S/D Mask in the second step, Via Hole Mask in the third step and ITO Mask in the fourth step.

The array substrate of the ADS type LCD manufactured by the above mentioned process has the following problems: there is water vapor residue in the common electrode ITO. A portion of the water vapor residue is due to the added water during the formation of the ITO (for example, using sputtering) for preventing the crystallization of the common electrode ITO during film formation. Another portion of the water vapor residue is due to water absorbed from the air after film formation of ITO. Water vapor residue produces bumps on the interface between the ITO and other layers, the bumps are prone to breakage in the high temperature vacuum process after the manufacture of the common electrode and gate, resulting in short circuit of data lines and gates, seriously affecting the yield of ADS products.

### SUMMARY

To this end, the embodiments of the invention provide an array substrate and a method for manufacturing the same. After film formation of ITO, an annealing process is performed. Water vapor residue in the ITO film can thus be released, thereby avoiding bumps on the interface between the ITO and other layers, and improving the yield of ADS products.

According to a first aspect, an embodiment of the present invention provides a method for manufacturing an array substrate. The method includes: forming an ITO film on a substrate, performing an annealing treatment on the substrate, forming a gate metal film on the ITO film, and processing the ITO film and the gate metal film to obtain a common electrode pattern and a gate pattern.

In an implementation of the embodiment, a temperature of the annealing treatment is 120 to 160° C.

In an implementation of the embodiment, a temperature of the annealing treatment is 140° C.

In an implementation of the embodiment, the duration of the annealing treatment is 30 minutes.

In an implementation of the embodiment, an atmosphere of the annealing treatment is nitrogen.

In an implementation of the embodiment, the step of processing the ITO film and the gate metal film to obtain a common electrode pattern and a gate pattern includes: etching the ITO film and the gate metal film with a gray scale mask etching process to obtain the common electrode pattern and the gate pattern.

In an implementation of the embodiment, the step of etching the ITO film and the gate metal film with a gray scale mask etching process to obtain the common electrode pattern and the gate pattern includes: coating a photoresist on the substrate; exposing the photoresist with a gray scale mask plate to form a photoresist pattern including a first portion and a second portion, the thickness of the first portion being less than the thickness of the second portion; and etching the substrate on which the photoresist pattern is formed to obtain the common electrode pattern and the gate pattern.

In an implementation of the embodiment, the step of etching the substrate on which the photoresist pattern is formed to obtain the common electrode pattern and the gate pattern includes: performing a first etching process on the substrate, etching the gate metal film and the ITO film not covered by the photoresist to obtain the common electrode pattern; removing the first portion of the photoresist pattern using a photoresist ashing process; performing a second etching process on the substrate, etching the gate metal film not covered by the photoresist to obtain the gate pattern; and removing residual photoresist.

In an implementation of the embodiment, the step of etching the ITO film and the gate metal film with a gray scale mask etching process to obtain the common electrode pattern and the gate pattern further includes: after etching the substrate on which the photoresist pattern is formed, annealing the substrate.

In an implementation of the embodiment, the method further includes: forming a semiconductor layer, a source and a drain on the substrate on which the common electrode pattern and the gate pattern are formed; forming a passivation layer on the substrate on which the semiconductor layer, the source and the drain are formed and forming a via hole; and forming a pixel electrode on the substrate on which the passivation layer and the via hole are formed.

According to a second aspect, an embodiment of the present invention further provides an array substrate. The array substrate is manufactured by the method according to the first aspect.

In the embodiments of the present invention, after film formation of ITO, an annealing process is performed. Water vapor residue in the ITO film can thus be released, thereby avoiding bumps on the interface between the ITO and other layers, and improving the yield of ADS products.

### BRIEF DESCRIPTION OF THE DRAWINGS

In order to more clearly illustrate the technical solutions in embodiments of the invention or in the prior art, the appended drawings needed to be used in the description of the embodiments or the prior art will be introduced briefly in the following. Obviously, the drawings in the following description are only some embodiments of the invention, and for those of ordinary skills in the art, other drawings may be obtained according to these drawings under the premise of not paying out creative work.

FIG. 1 is a flow chart of a method for manufacturing an array substrate according to an embodiment of the invention;

FIG. 2 is a flow chart of a method for manufacturing an array substrate according to another embodiment of the invention;

FIG. 2a is a structural schematic diagram in a production process of an array substrate according to an embodiment of the invention;

FIG. 2b is a structural schematic diagram in a production process of an array substrate according to an embodiment of the invention;

FIG. 2c is a structural schematic diagram in a production process of an array substrate according to an embodiment of the invention;

FIG. 2d is a structural schematic diagram in a production process of an array substrate according to an embodiment of the invention;

FIG. 2e is a structural schematic diagram in a production process of an array substrate according to an embodiment of the invention;

FIG. 2f is a structural schematic diagram in a production process of an array substrate according to an embodiment of the invention; and

FIG. 2g is a structural schematic diagram in a production process of an array substrate according to an embodiment of the invention;

### DETAILED DESCRIPTION OF THE INVENTION

In the following, the technical solutions in embodiments of the invention will be described clearly and completely in connection with the drawings in the embodiments of the invention. Obviously, the described embodiments are only part of the embodiments of the invention, and not all of the embodiments. Based on the embodiments in the invention, all other embodiments obtained by those of ordinary skills in the art under the premise of not paying out creative work pertain to the protection scope of the invention.

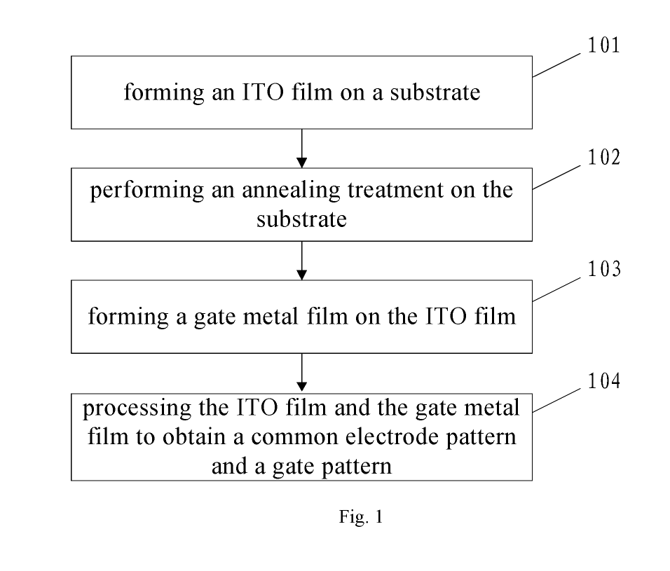

FIG. 1 is a flow chart of a method for manufacturing an array substrate according to an embodiment of the invention. As shown in FIG. 1, the method includes:

Step 101: forming an ITO (Indium Tin Oxide) film on a substrate.

Step 102: performing an annealing treatment on the substrate.

Step 103: forming a gate metal film on the ITO film.

Step 104: processing the ITO film and the gate metal film to obtain a common electrode pattern and a gate pattern.

The common electrode pattern and the gate pattern can be obtained by processing the ITO film and the gate metal film with a one-time composition process, a detailed description can be seen below. The common electrode pattern and the gate pattern can also be obtained by processing the ITO film and the gate metal film without the one-time composition process (instead, for example, using a two-time composition process), which is not described in detail herein.

In the embodiments of the present invention, after film formation of ITO, an annealing process is performed. Water vapor residue in the ITO film can thus be released, thereby avoiding bumps on the interface between the ITO and other layers, and improving the yield of ADS products.

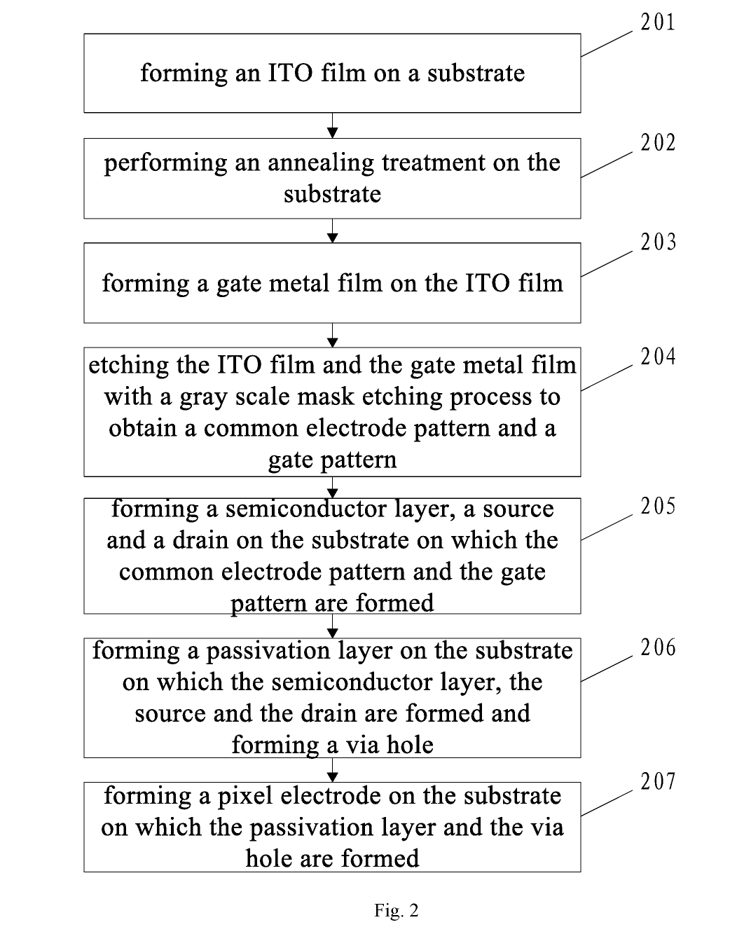

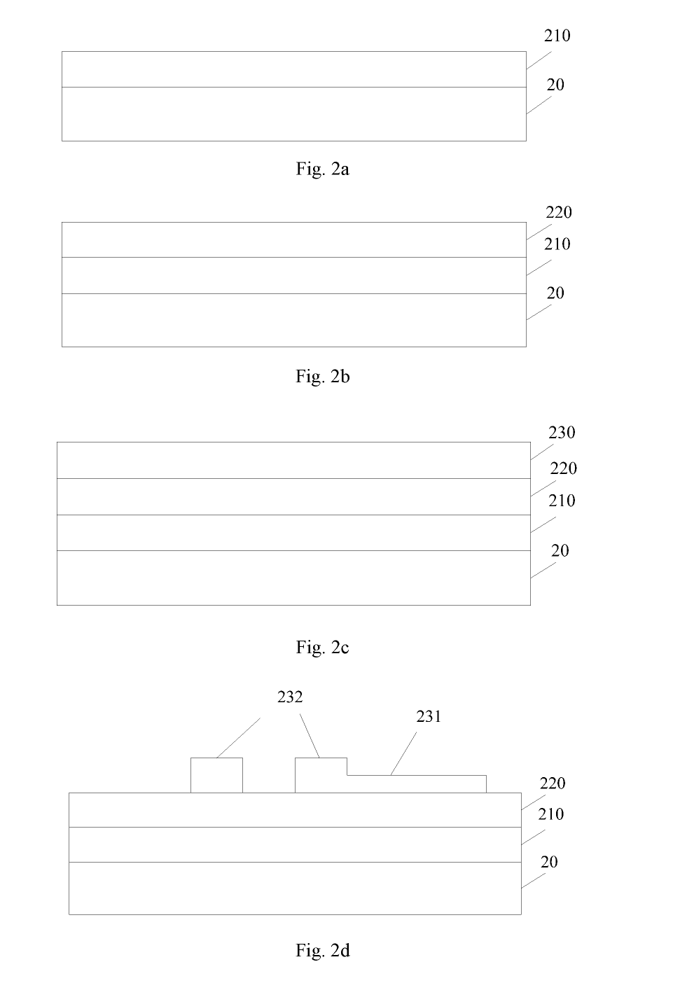

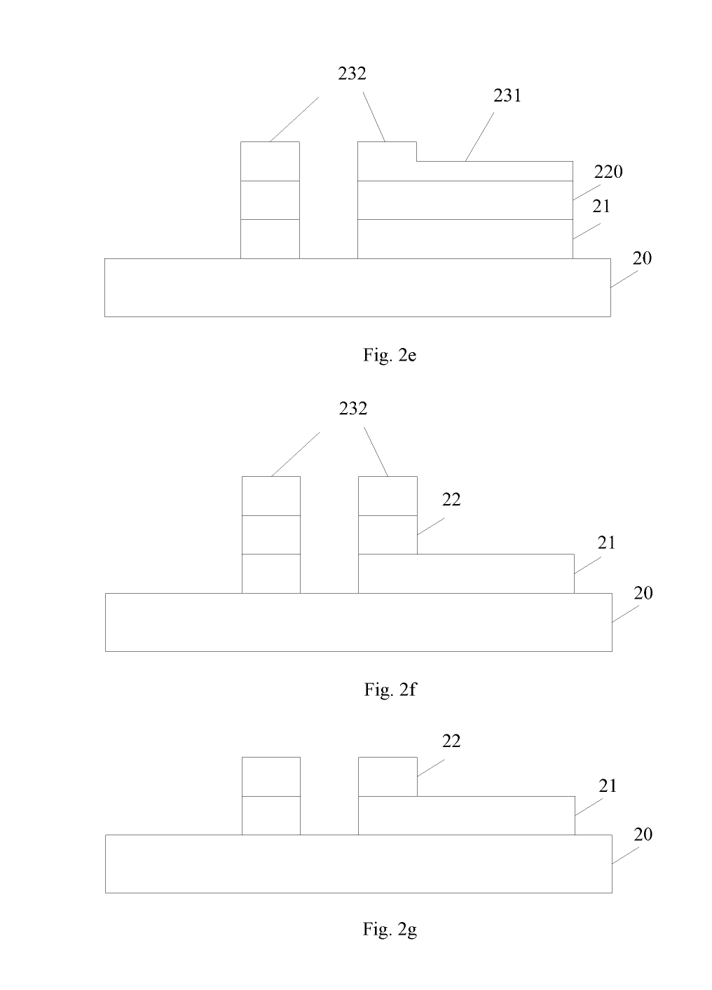

FIG. 2 is a flow chart of a method for manufacturing an array substrate according to another embodiment of the invention. As shown in FIG. 2, the method includes:

Step 201: forming an ITO film on a substrate.

As shown in FIG. 2, an ITO film 210 is formed on a substrate 20.

Those skilled in the art can understand that the ITO film can also be formed with a process such as magnetron sputtering, chemical vapor deposition (CVD), spray pyrolysis and sol-gel process.

Step 202: performing an annealing treatment on the substrate.

The temperature of the annealing treatment can be 120 to 160° C. In some embodiments of the invention, the temperature of the annealing treatment is 120 to 160 ° C., thereby releasing water vapor sufficiently.

Optionally, the temperature of the annealing treatment is 140 ° C. In some embodiments of the invention, the temperature of the annealing treatment is 140 ° C., thereby balancing the adequacy of the water vapor release and the degree of crystallization.

The duration of the annealing treatment can be 30 minutes. In some embodiments of the invention, the duration of the annealing treatment is 30 minutes, thereby releasing water vapor sufficiently.

The atmosphere of the annealing treatment is nitrogen. Certainly, in the present embodiment, other common annealing atmospheres can also be selected in addition to nitrogen as an annealing atmosphere.

Step 203: forming a gate metal film on the ITO film.

In particular, the gate metal film can be formed on the ITO film with a sputtering process.

As shown in FIG. 2b, a gate metal film 220 is formed on the substrate 20 on which the ITO film 210 is formed.

Those skilled in the art can understand that before forming the gate metal film, an insulating layer may be formed on the ITO film by spraying, spin coating, sputtering, etc.

Step 204: etching the ITO film and the gate metal film with a gray scale mask etching process to obtain a common electrode pattern and a gate pattern.

In some embodiments of the invention, a gray scale mask etching process is used to realize a one-time composition process to obtain the common electrode pattern and the gate pattern, reducing the production steps.

In particular, the step of etching the ITO film and the gate metal film with a gray scale mask etching process to obtain the common electrode pattern and the gate pattern includes the following steps:

Step 1, coating a photoresist on the substrate. As shown in FIG. 2c, a photoresist 230 is coated on the substrate 20 on which the ITO film 210 and the gate metal film 220 are formed.

Step 2, exposing the photoresist with a gray scale mask plate to form a photoresist pattern including a first portion 231 and a second portion 232, the thickness of the first portion 231 being less than the thickness of the second portion 232. As shown in FIG. 2d, the photoresist pattern including a first portion and a second portion.

Step 3, etching the substrate on which the photoresist pattern is formed to obtain the common electrode pattern and the gate pattern.

Step 3 can be illustrated by FIGS. 2e-2g. In particular, Step 3 can include: performing a first etching process on the substrate 20, etching the gate metal film 210 and the ITO film 220 not covered by the photoresist to obtain the common electrode pattern 21 (as shown in FIG. 2e); removing the first portion 231 of the photoresist pattern using a photoresist ashing process; performing a second etching process on the substrate 20, etching the gate metal film 220 not covered by the photoresist to obtain the gate pattern 22 (as shown in FIG. 2f); and removing residual photoresist (i.e., the second portion 232, as shown in FIG. 2g).

The step of etching the ITO film and the gate metal film with a gray scale mask etching process to obtain the common electrode pattern and the gate pattern further includes: after etching the substrate on which the photoresist pattern is formed, annealing the substrate.

Step 205: forming a semiconductor layer, a source and a drain on the substrate on which the common electrode pattern and the gate pattern are formed. In particular, in Step 205, the semiconductor layer, the source and the drain can be formed on the substrate with a one-time composition process. In step 205, the semiconductor layer can be firstly formed, and then the source and the drain can be formed with a composition process. The source and the drain can also be collectively referred to as a source drain electrode.

Step 206: forming a passivation layer on the substrate on which the semiconductor layer, the source and the drain are formed and forming a via hole. The via hole is formed on the passivation layer and exposes the drain in the source drain electrode.

Step 207: forming a pixel electrode on the substrate on which the passivation layer and the via hole are formed. The pixel electrode is connected to the drain.

Step 205 to Step 207 can be realized with the existing manufacture process for the ADS type TFT LCD array substrate.

In the embodiment of the invention, after film formation of ITO, an annealing process is performed. Water vapor residue in the ITO film can thus be released, thereby avoiding bumps on the interface between the ITO and other layers, and improving the yield of ADS products.

An embodiment of the present invention further provides an array substrate. The array substrate is manufactured by the method corresponding to FIG. 1 or FIG. 2.

In the manufacture process of the array substrate, after film formation of ITO, an annealing process is performed. Water vapor residue in the ITO film can thus be released, thereby avoiding bumps on the interface between the ITO and other layers, and improving the yield of ADS products.

The above embodiments are only used for explanations rather than limitations to the present invention, the ordinary skilled person in the related technical field, in the case of not departing from the spirit and scope of the present invention, may also make various modifications and variations, therefore, all the equivalent solutions also belong to the scope of the present invention, the patent protection scope of the present invention should be defined by the claims

1. A method for manufacturing an array substrate, comprising:
forming an ITO film on a substrate;
performing an annealing treatment on the substrate;
forming a gate metal film on the ITO film; and
processing the ITO film and the gate metal film to obtain a common electrode pattern and a gate pattern.

2. The method according to claim 1, wherein a temperature of the annealing treatment is 120 to 160° C.

3. The method according to claim 2, wherein a temperature of the annealing treatment is 140° C.

4. The method according to claim 1, wherein the duration of the annealing treatment is 30 minutes.

5. The method according to claim 1, wherein an atmosphere of the annealing treatment is nitrogen.

6. The method according to claim 1, wherein the step of processing the ITO film and the gate metal film to obtain a common electrode pattern and a gate pattern comprises: etching the ITO film and the gate metal film with a gray scale mask etching process to obtain the common electrode pattern and the gate pattern.

7. The method according to claim 6, wherein the step of etching the ITO film and the gate metal film with a gray scale mask etching process to obtain the common electrode pattern and the gate pattern comprises:
coating a photoresist on the substrate;
exposing the photoresist with a gray scale mask plate to form a photoresist pattern comprising a first portion and a second portion, the thickness of the first portion being less than the thickness of the second portion; and
etching the substrate on which the photoresist pattern is formed to obtain the common electrode pattern and the gate pattern.

8. The method according to claim 7, wherein the step of etching the substrate on which the photoresist pattern is formed to obtain the common electrode pattern and the gate pattern comprises:
performing a first etching process on the substrate, etching the gate metal film and the ITO film not covered by the photoresist to obtain the common electrode pattern;
removing the first portion of the photoresist pattern using a photoresist ashing process;
performing a second etching process on the substrate, etching the gate metal film not covered by the photoresist to obtain the gate pattern; and
removing residual photoresist.

9. The method according to claim 7, wherein the step of etching the ITO film and the gate metal film with a gray scale mask etching process to obtain the common electrode pattern and the gate pattern further comprises:
after etching the substrate on which the photoresist pattern is formed, annealing the substrate.

10. The method according to claim 1, further comprising:
forming a semiconductor layer, a source and a drain on the substrate on which the common electrode pattern and the gate pattern are formed;
forming a passivation layer on the substrate on which the semiconductor layer, the source and the drain are formed and forming a via hole; and
forming a pixel electrode on the substrate on which the passivation layer and the via hole are formed.

11. An array substrate manufactured by the method according to claim 1.

12. The array substrate according to claim 11, wherein a temperature of the annealing treatment is 120 to 160° C.

13. The array substrate according to claim 12, wherein a temperature of the annealing treatment is 140° C.

14. The array substrate according to claim 11, wherein the duration of the annealing treatment is 30 minutes.

15. The array substrate according to claim 11, wherein an atmosphere of the annealing treatment is nitrogen.

16. The array substrate according to claim 11, wherein the step of processing the ITO film and the gate metal film to obtain a common electrode pattern and a gate pattern comprises: etching the ITO film and the gate metal film with a gray scale mask etching process to obtain the common electrode pattern and the gate pattern.

17. The array substrate according to claim 16, wherein the step of etching the ITO film and the gate metal film with a gray scale mask etching process to obtain the common electrode pattern and the gate pattern comprises:
coating a photoresist on the substrate;
exposing the photoresist with a gray scale mask plate to form a photoresist pattern comprising a first portion and a second portion, the thickness of the first portion being less than the thickness of the second portion; and
etching the substrate on which the photoresist pattern is formed to obtain the common electrode pattern and the gate pattern.

18. The array substrate according to claim 17, wherein the step of etching the substrate on which the photoresist pattern is formed to obtain the common electrode pattern and the gate pattern comprises:
performing a first etching process on the substrate, etching the gate metal film and the ITO film not covered by the photoresist to obtain the common electrode pattern;
removing the first portion of the photoresist pattern using a photoresist ashing process;
performing a second etching process on the substrate, etching the gate metal film not covered by the photoresist to obtain the gate pattern; and
removing residual photoresist.

19. The array substrate according to claim 17, wherein the step of etching the ITO film and the gate metal film with a gray scale mask etching process to obtain the common electrode pattern and the gate pattern further comprises:
after etching the substrate on which the photoresist pattern is formed, annealing the substrate.

20. The array substrate according to claim 11, wherein the method further comprises:
forming a semiconductor layer, a source and a drain on the substrate on which the common electrode pattern and the gate pattern are formed;
forming a passivation layer on the substrate on which the semiconductor layer, the source and the drain are formed and forming a via hole; and
forming a pixel electrode on the substrate on which the passivation layer and the via hole are formed.
